(19) United States
(12) Patent Application Publication
(10) Pub. No.: US 2010/0006316 A1
(43) Pub. Date: Jan. 14, 2010

(54) Protective cover plate

(76) Inventor: Brandon Begnaud, Breaux Bridge, LA (US)

Correspondence Address: KEATY LAW FIRM, LLC, 365 CANAL STREET, Suite 2410, NEW ORLEANS, LA, 70130, US

(21) Appl. No.: 12/217,806

(22) Filed: Jul. 9, 2008

(51) Int. Cl. H05K 5/03

(52) U.S. Cl. 174/66

(57) ABSTRACT

A cover for protecting an electric wiring device from liquid paint or dust snaps onto the electric wiring device after the cover plate has been removed. The protective cover has a planar body with protrusions configured for receiving an on/off switch, or a socket therein.

### BACKGROUND OF THE INVENTION

This invention relates to cover plates for use with electrical wiring devices, such as wall mounted switches and/or electrical sockets. More particularly, the invention relates to a protective cover plate that can be detachably positioned on the electric wiring device that is secured in a conventional manner and recessed in the wall of a building.

During painting of walls, care should be exercised to prevent liquid paint and dust from entering the wall-recessed electrical wiring devices. To solve the problem, the construction industry developed a number of solutions. One of such solutions is to use a masking tape to cover the electric outlet or designate a border around the electric box. The tape has an adhesive material on one side, allowing the tape to be adhesively secured to the wall surrounding the electric box.

While this solution offers some advantages, the removal of the tape from the wall and from the electric wiring device is often time-consuming and cumbersome. Additionally, the tape may tear and particles of the tape can be inadvertently left in the electric box.

The present invention contemplates elimination of drawbacks associated with the conventional technique and provision of a protective cover plate for electrical boxes that can be easily positioned and removed from the electric wiring device after the painting has been completed.

### SUMMARY OF THE INVENTION

It is therefore an object of the present invention provides a cover plate for a wall mounted electric wiring device, such as an electrical switch or a socket.

It is another object of the present invention to provide an easy to use cover plate that can be readily positioned in a protective covering relationship over an electrical device mounted inside the electric box and removed when not required.

These and other objects of the present invention are achieved through a provision of a cover for a wall-mounted electric wiring device mounted in a wall-recessed box. The electric wiring device can be an electric socket and/or on/off switch. The cover comprises a generally planar body having a back surface for detachably engaging with the electric wiring device and a front surface. A depression is formed in the back surface corresponding in shape and size to a hollow protrusion projecting from the front surface, said protrusion being sized and configured for covering at least a front portion of the electric wiring device when the planar body is snapped onto the electric wiring device.

The cover can be made from a thin plastic material that is molded or stamped to form the depression in the back surface and force the protrusion outwardly from the front surface. The cover can be formed to cover the electric wiring device containing an on/off switch or one or more electric socket, such as for instance a three-pronged socket conventionally used in electrical engineering.

### BRIEF DESCRIPTION OF THE DRAWINGS

Reference will now be made to the drawings, wherein like parts are designed by like numerals and wherein

FIG. 1 is a perspective view of a protective cover plate of the present invention configured for use on a switch plate.

FIG. 2 is a perspective view of a cover plate of the present invention configured for use on a socket.

FIG. 3 is a side view of an outlet cover plate mounted on a socket outlet.

FIG. 4 is a perspective view of the switch cover plate mounted on an electrical switch device.

FIG. 5 is a side view of the switch cover plate of the present invention.

FIG. 6 is a side view of the socket cover plate of the present invention.

FIG. 7 is a front view of a combination cover plate designed to accommodate the switch and/or socket electrical wiring devices.

FIG. 8 is a side view of the cover plate shown in FIG. 7.

### DETAILED DESCRIPTION OF THE PREFERRED EMBODIMENT

Turning now to the drawings in more detail, numeral 10 designates the protective cover plate of the present invention configured for protecting an electric switch. The cover plate 10 comprises a generally planar body 12 having a first side 14, a second side 16, a first end 18 and a second end 20. The planar body 12 is dimensioned to fit over an electrical device, such as a switch 30 shown in phantom lines in FIG. 4.

The planar body 12 has a back surface 23 and a front surface 24. The back surface 24 is provided with a depression, which corresponds to a hollow protrusion 22, which extends outwardly from the front surface 24 of the body 12. The protrusion 22 is configured for receiving a conventional switch 32 of an electrical wiring device 30. The protrusion 22 comprises an outwardly projecting peripheral wall 28 which is sized and configured to snap onto a wall 34 surrounding the light switch 32. An outermost portion 29 of the protrusion 22 is configured to accommodate extension of the light switch 32 therein. The peripheral wall 28 is configured to detachably engage the corresponding light switch protrusion of the device 30 when the protective cover plate 10 is pressed onto the wiring device 30. The peripheral wall 28 is allowed to slightly expand and then resiliently retract while snapping onto the wall 34 of the wiring device 30.

The body 12 of the cover plate 10 is formed from a thin waterproof flexible material, for instance plastic, and sized to cover the electrical wiring device and protect the inside of the wiring device 30 from paint, dust and other debris while the necessary work is being conducted in the building.

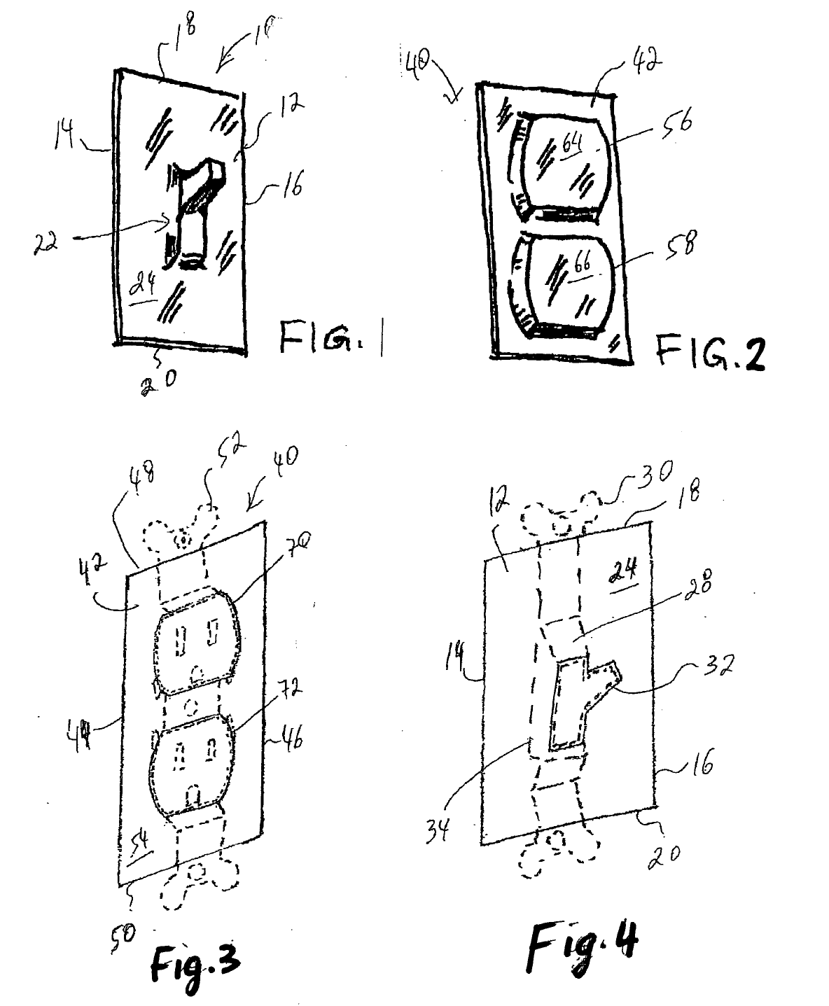

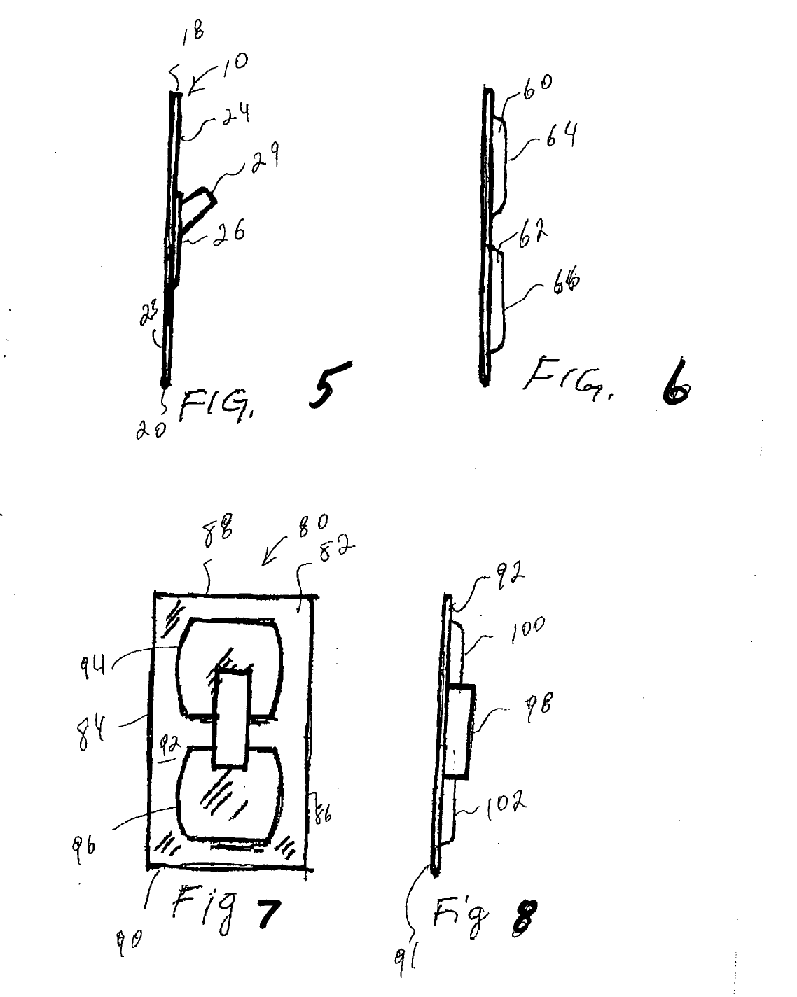

Turning now to FIGS. 2 and 3, the socket cover plate 40 designed for use with an electrical wiring device, such as electrical socket is shown in detail. As can be seen in the drawings, the cover plate 40 comprises a planar body 42 having a first side 44, a second side 46, a first end 48 and a second end 50. The dimensions of the body 42 are selected to substantially cover the electric wiring device 52 that is secured in a wall mounted electric box (not shown).

The planar body 42, similar to the body 10, has a minimal thickness so as not to extend substantially from the wall-mounted electric box. The planar body 42 has a back surface 53 and a substantially smooth front surface 54. A depression is formed in the back surface 53 and one more hollow protrusions corresponding to the back surface depression(s) projects outwardly from the front surface 54.

The protrusions 56, 58 are each defined by a peripheral protruding wall 60, 62 (FIG. 6) and a front wall 64, 66 respectively. Each of the protrusions 56 and 58 is sized and configured to snap onto an electric wiring device in a covering relationship over at least a portion thereof. The electrical wiring device in this case is a three-prong electrical socket. The protrusions 56 and 58 extend outwardly from the front surface 54 of the cover plate body 42 to a distance suitable for accommodating the outward extension of the sockets 70, 72. The peripheral walls 60 and 62 have the ability to slightly stretch and then snap onto the walls of the electrical outlet devices 70, 72, thereby retaining the cover plate 40 over the electric wiring device 52.

Turning now to the embodiment of FIGS. 7 and 8, a combination cover plate 80 is shown in more detail. The cover plate 80 comprises a generally planar body 82 comprising a first side 84, a second side 86, a first end 88 and a second end 90. The cover plate 80 is provided with several protrusions, which extend from depressions formed in the back surface 91 to a front surface 92 of the body 82.

A first protrusion member 94 is formed to accommodate a socket, similar to the socket 70. The second protrusion member 96 is configured to generally cover and snap onto the three-prong socket similar to the socket 72, which is vertically spaced from and aligned with the socket 70. A third protrusion member 98 extends between the protrusion members 94 and 96 to a distance greater than the front surface 100 and 102 of the protrusions 94 and 96, respectively. The protrusion member 98 is shaped to accommodate an on/off switch similar to a switch 32, when mounted on the electric wiring device.

Similarly to the cover plates 10 and 40, the cover plate 80 is formed from a moisture-impermeable flexible material, for instance thin plastic, allowing the protrusions to snap onto the electrical wiring devices such as the socket or a switch. The thickness of the cover plates 10, 40 and 80 is minimal, thereby providing a protective cover without adding any substantial thickness to the electrical wiring device.

The cover plates of the present invention do not require any adhesive or mechanical attachment member for securing on the electrical wiring devices. The snap-on feature allows the plates to be easily positioned and removed from the electrical wiring devices upon demand. If desired, the plates 10, 40 and 80 can be reused in other applications while protecting the electrical wiring device from dust and moisture when necessary. The cover plates 10, 40 and 80 can be formed by stamping or molding, or by other techniques that will be apparent to those skilled in the art. The cover plates can be made rectangular, oval or in any other suitable shape to accommodate the electrical wiring devices.

Many other changes and modifications can be made in the design of the present invention without departing from the spirit thereof. I therefore pray that my rights to the present invention be limited only by the scope of the appended claims.

I claim:

1. A cover for a wall-mounted electric wiring device, comprising a generally planar body having a back surface for detachably engaging with the electric wiring device and a front surface, said planar body being formed with a depression in the back surface corresponding in shape and size to a hollow protrusion projecting from the front surface, said protrusion being sized and configured for covering at least a front portion of the electric wiring device when the planar body is snapped onto the electric wiring device.

2. The cover of claim 1, wherein said protrusion is configured to receive an on/off electric switch therein, while a peripheral wall formed by the protrusion is configured for engaging the electric wiring device containing the on-off switch.

3. The cover of claim 1, wherein said protrusion is configured to cover at least a front panel of an electric socket, while a peripheral wall formed by the protrusion is configured for engaging sidewall of the electric wiring device.

4. The cover of claim 1, wherein said protrusion comprises at least one member configured to receive an on/off electric switch therein and at least one second member configured for covering at least a front panel of an electric socket.

5. The cover of claim 1, wherein said protrusion comprises a first member configured to cover at least a front panel of an electric socket, a second member configured to cover at least a front panel of a second vertically aligned socket, and a third member configured to receive an on/off switch therein.

6. The cover of claim 5, wherein said third member of the protrusion extends between the first member and the second member.

7. The cover of claim 1, wherein said planar body is formed from a flexible material capable of snugly engaging the electric wiring device.

8. A cover for an electric wiring device mounted in a wall-recessed box receptacle, said cover comprising a generally planar body having a back surface for detachably engaging with the electric wiring device and a front surface, said back surface being formed with a depression corresponding in shape and size to a hollow protrusion projecting from the front surface, said protrusion being sized and configured for receiving an on/off switch therein, while said planar body covers at least a front portion of the electric wiring device containing said on/off switch when said cover is snapped onto said electric wiring device.

9. The cover of claim 9, wherein said protrusion comprises a peripheral sidewall capable of detachably engaging said electric wiring device.

10. The cover of claim 8, wherein said planar body is formed from a flexible material capable of snugly engaging the electric wiring device.

11. A cover for an electric wiring device mounted in a wall-recessed box receptacle, said cover comprising a generally planar body having a back surface for detachably engaging with the electric wiring device and a front surface, said back surface being formed with a depression corresponding in shape and size to a hollow protrusion projecting from the front surface, said protrusion being sized and configured for receiving an least a portion of an electric socket therein, while said planar body covers at least a front portion of the electric wiring device containing said electric socket when said cover is snapped onto said electric wiring device.

12. The cover of claim 1, wherein said protrusion comprises a first member configured for covering a first electric socket, and a second member configured for covering a second electric socket vertically spaced from the first electric socket.

13. The cover of claim 11, wherein said first member of the protrusion comprises a first peripheral sidewall capable of detachably engaging said first electric socket, and a second peripheral sidewall capable of detachably engaging said second electric socket.

14. A cover for an electric wiring device mounted in a wall-recessed box receptacle, said cover comprising a generally planar body having a back surface for detachably engaging with the electric wiring device and a front surface, said back surface being formed with a depression corresponding in shape and size to a hollow protrusion projecting from the front surface, said protrusion comprising a first member configured for engaging a electric socket, a second member configured for engaging a second electric socket vertically spaced from the first electric socket when said cover is snapped onto said electric wiring device.

15. The cover of claim 14, wherein said protrusion comprises a third member extending between the first member and the second member for receiving an on/off switch therein.

16. The cover of claim 14, wherein said planar body is formed from a flexible material capable of snugly engaging the electric wiring device.
